(19) United States
(12) Patent Application Publication
(10) Pub. No.: US 2026/0240050 A1
(43) Pub. Date: Aug. 13, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Sang Hyun JIN, Incheon (KR); Hyun Goo CHA, Incheon (KR); Jin Suk JEONG, Incheon (KR)

(73) Assignee: Amkor Technology Singapore Holding Pte. Ltd., Valley Point #12-03 (SG)

(21) Appl. No.: 19/050,824

(22) Filed: Feb. 11, 2025

(51) Int. Cl. H01L 23/498; H01L 23/13

(52) U.S. Cl. CPC H10W 90/701; H10W 70/65; H10W 70/68

(57) ABSTRACT

In one example, an electronic device includes a substrate including a substrate top side, a substrate lower side, a dielectric structure, and a conductive structure, which includes substrate inner terminals adjacent to the substrate top side, and substrate outer terminals adjacent to the substrate lower side. An electronic component includes a first side coupled to the substrate inner terminals, a second side, and a lateral side. An interconnect module includes interconnects laterally spaced apart, each of the interconnects including a first lateral side, a second lateral side, a first end, and a second end; and a seed layer on the first lateral side. A package body covers the substrate top side, portions of the interconnect module and the lateral side of the electronic component. The first end of each of the interconnects is coupled to the substrate inner terminals. Other examples and related methods are also disclosed herein.

### CROSS-REFERENCES TO RELATED APPLICATIONS

Not applicable

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 illustrates a cross-sectional view of an example electronic device.

FIGS. 2A, 2B, 2C, 2D, and 2E illustrates cross-sectional views of an example method for manufacturing an example electronic device.

FIGS. 3A, 3B, 3C, 3D, 3E, 3F, and 3G illustrate cross-sectional views of an example method for manufacturing an interconnect module.

FIG. 3H illustrates a perspective view of an example interconnect module at a later stage of manufacture.

FIG. 3I illustrates a perspective view of an example interconnect module at a later stage of manufacture.

FIG. 3J illustrates a perspective view of an example interconnect module at a later stage of manufacture.

FIG. 4 illustrates a cross-sectional view of an example electronic device.

FIGS. 5A, 5B, 5C, 5D, 5E, 5F, and 5G illustrate cross-sectional views of an example method for manufacturing an example electronic device.

FIGS. 6A, 6B, 6C, 6D, 6E, 6F, 6G, and 6H illustrate cross-sectional views of an exemplary method for manufacturing an interconnect module.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in the present disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. Unless specified otherwise, the term “coupled” can refer to a mechanical or electrical coupling.

### DESCRIPTION

The present description includes, among other features, structures and associated methods that relate to electronic devices using modular interconnect structures. More particularly, structures and methods are described that provide pillar interconnect modules with finer pitch and increased height compared to previous approaches. In some examples, the conductor heights for the interconnect module are provided by forming (for example, by plating) the structures lengthwise in the x or y directions as opposed to the z direction. In some examples, the height and aspect ratio of the interconnect module can be selected using a singulation process. In some examples, the interconnect modules can comprise vertical redistribution configurations. In some examples, the interconnect modules include a stiffener along one side of the interconnect module. Among other things, the structures and methods provide for improved integration and smaller package size.

In an example, an electronic device includes a first substrate including a first substrate top side, a first substrate lower side opposite to the first substrate top side, a first dielectric structure, and a first conductive structure including first substrate inner terminals adjacent to the first substrate top side, and first substrate outer terminals adjacent to the first substrate lower side and coupled to the first substrate inner terminals. A first electronic component includes a first side coupled to the first substrate inner terminals, a second side opposite to the first side, and a lateral side connecting the first side to the second side. An interconnect module includes interconnects laterally spaced apart, wherein each of the interconnects comprising a first lateral side, a second lateral side opposite to the first lateral side, a first end, and a second end opposite to the first end; and a seed layer on the first lateral side but not the second lateral side of each of the interconnects. A package body covering the first substrate top side, portions of the interconnect module and the lateral side of the first electronic component. The first end of each of the interconnects is coupled to the first substrate inner terminals.

In an example, an electronic device includes a first substrate including a first substrate top side, a first substrate lower side opposite to the first substrate top side, a first dielectric structure, and a first conductive structure including first substrate inner terminals adjacent to the first substrate top side, and first substrate outer terminals adjacent to the first substrate lower side and coupled to the first substrate inner terminals. A second substrate includes a second substrate top side, a second substrate lower side opposite to the second substrate top side, a second dielectric structure, and a second conductive structure including second substrate inner terminals adjacent to the second substrate lower side, and second substrate outer terminals adjacent to the second substrate top side and coupled to the second substrate inner terminals. A first electronic component includes a first side coupled to the first substrate inner terminals, a second side opposite to the first side, and a lateral side connecting the first side to the second side. An interconnect module including interconnects laterally spaced apart, wherein each of the interconnects comprising a first lateral side, a second lateral side opposite to the first lateral side, a first end, and a second end opposite to the first end; and a seed layer on the first lateral side of each of the interconnects. A package body covers the first substrate top side, the second substrate lower side, portions of the interconnect module and the lateral side of the first electronic component. The interconnect module comprises at least two layers of the interconnects, the first end of each of the interconnects is coupled to the first substrate inner terminals, and the second end of each of the interconnects is coupled to the second substrate inner terminals.

In an example, a method of manufacturing an electronic device includes providing a first electronic component including a first side, a second side opposite to the first side, a lateral side connecting the first side to the second side, and connectors adjacent to the first side. The method includes providing an interconnect module including interconnects laterally spaced apart, wherein each of the interconnects comprising a first lateral side, a second lateral side opposite to the first lateral side, a first end, and a second end opposite to the first end; and a seed layer on the first lateral side but not the second lateral side of each of the interconnects. The method includes providing a package body covering portions of the interconnect module and the first electronic component. The method includes providing a first substrate including a first dielectric structure, and a first conductive structure including first substrate inner terminals, and first substrate outer terminals exposed from the first dielectric structure and coupled to the first substrate inner terminals. The first end of each of the interconnects and the connectors are coupled to the first substrate inner terminals.

Other examples are included in the present disclosure. Such examples may be found in the figures, in the claims, or in the description of the present disclosure.

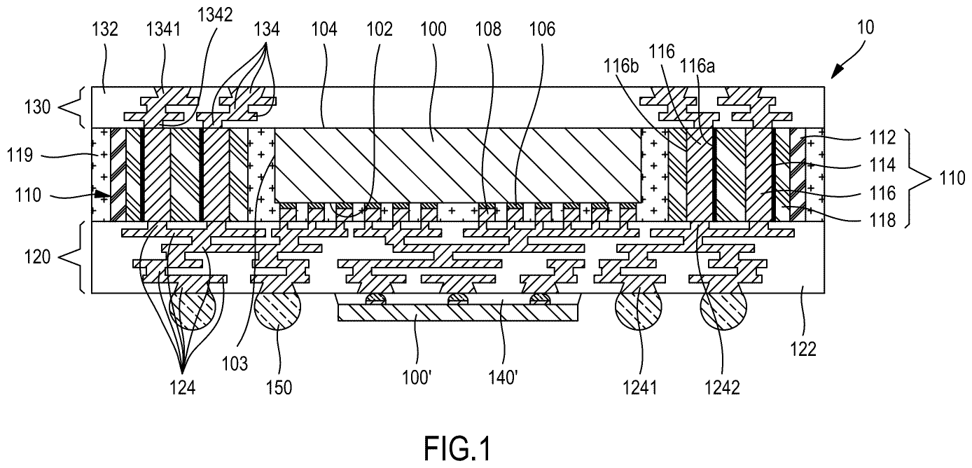

FIG. 1 illustrates a cross-sectional view of example electronic device 10. In the example illustrated in FIG. 1, electronic device 10 can comprise electronic components 100 and 100′, interconnect module 110, package body 119, first substrate 120, second substrate 130, underfill 140′, and external interconnects 150.

Electronic component 100 can comprise first side 102, second side 104 opposite to first side 102, and a lateral side 103 connecting first side 102 to second side 104. In some examples, electronic component 100 can comprise contact pads 106 and connectors 108 on first side 102 of electronic component 100. In the present example, first side 102 faces first substrate 120 and second side 104 faces second substrate 130.

In the present example, interconnect module 110 can comprise stiffener 112, seed layers 114, interconnects 116, and body 118. Interconnect module 110 is configured as a vertical interconnect structure that provides an interconnect between first substrate 120 and second substrate 130. In some examples, stiffener 112 is on one side only of interconnect module 110, such as the side facing outward or away from the electronic component 100. In some examples, the opposite side and the ends of interconnect module 110 are devoid of stiffener 112. In some examples, seed layers 114 are on one lateral side only (for example, lateral side 116a) of interconnects 116. In some examples, the other lateral sides (for example, lateral side 116b) and the ends of interconnects 116 are devoid of seed layer 114. In the present example, lateral side 116a of interconnects 116 is orthogonal to first substrate 120 and second substrate 130 and is parallel to lateral side 103 of electronic component 100. Body 118 can comprise or be referred to as an insulative body that electrically isolates adjacent interconnects 116 in interconnect module 110. Interconnects 116 can comprise or be referred to as pillars, elongate pillars, plated pillars, or elongate plated pillars. In the present example, stiffener 112 provides an outer lateral side of interconnect module 110 that faces to the outside of electronic device 10. Interconnect module 110 of FIG. 1 is an example of an interconnect module comprising at least two layers of interconnects 116. In the present example, the two layers are vertically oriented in a side-by-side configuration.

In some examples, first substrate 120 comprises dielectric structure 122 and conductive structure 124. Conductive structure 124 can comprise substrate inner terminals 1241 positioned on a first side of the first substrate and substrate outer terminals 1242 positioned on a second side of first substrate 120. First substrate 120 can comprise a top side (for example, the side adjoining interconnect module 110 and electronic component 100) and a lower side opposite to the top side (for example, the side adjacent to electronic component 100′).

Second substrate 130 can comprise dielectric structure 132 and conductive structure 134. Conductive structure 134 can comprise substrate inner terminals 1341 positioned on a first side of second substrate 120 and substrate outer terminals 1342 positioned on a second side of the second substrate. Substrate outer terminals 1342 can be coupled to substrate inner terminals 1341 through vias and traces within the dielectric structure 132. Second substrate 130 can comprise an inner side (for example, the side adjoining interconnect module 110, package body 119, and second side 104 of electronic component 100), and an outer side opposite to the inner side. The inner side of second substrate 130 can also comprise or be referred to as a second substrate lower side, and the outer side of second substrate can comprise or be referred to a second substrate top side.

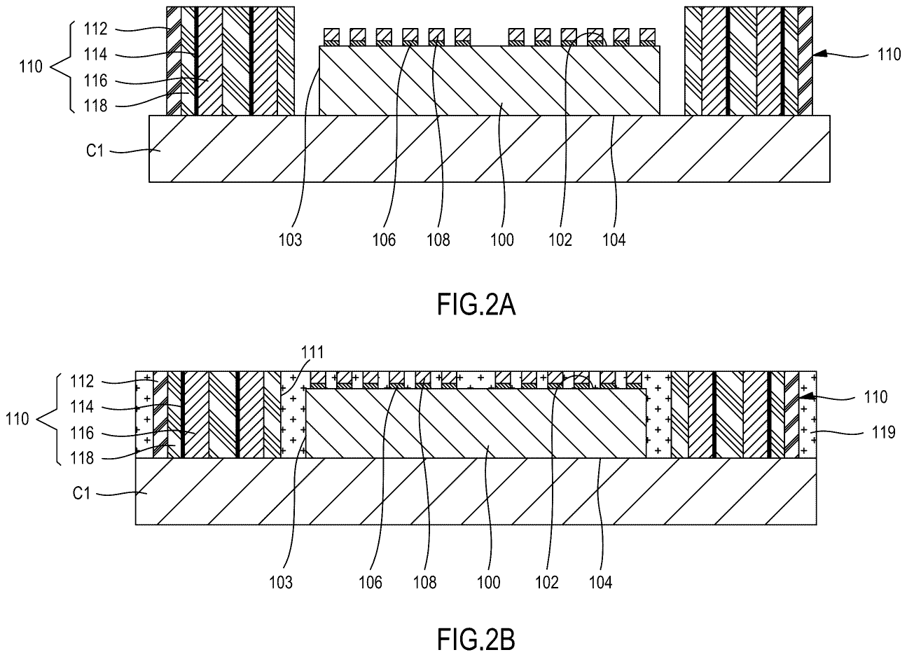

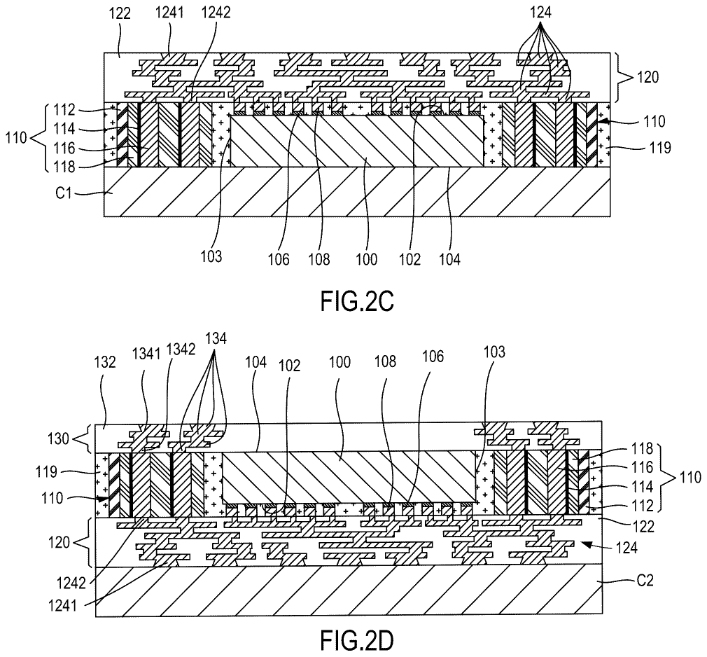

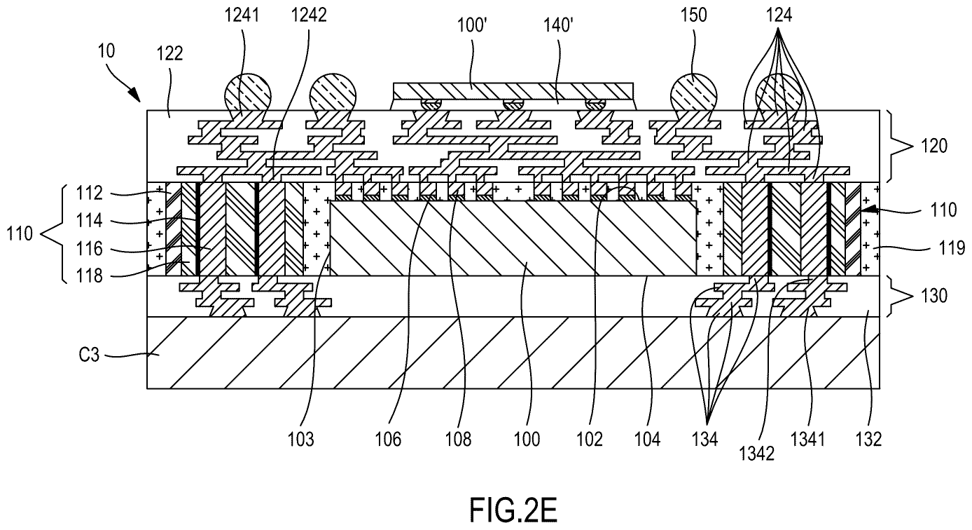

FIGS. 2A to 2E illustrate cross-sectional views of an example method for manufacturing example electronic device 10.

FIG. 2A illustrates a cross-sectional view of electronic device 10 at an early stage of manufacture. In the example illustrated in FIG. 2A, electronic component 100 and interconnect module 110 can be provided on the surface of carrier C1.

In some examples, first side 102 of electronic component 100 can comprise or be referred to as an active side, and second side 104 can comprise or be referred to as an inactive side. Electronic component 100 can comprise a lateral side 103 connecting first side 102 to second side 104.

In some examples, electronic component 100 can comprise contact pads 106 adjacent to first side 102. Contact pads 106 can be provided spaced apart from each other in a row or column direction on first side 102. In some examples, contact pads 106 can be bond pads exposed through a silicon oxide (SiO₂) film or a silicon nitride (SiN) film, or redistribution layer pads exposed by a dielectric material. In some examples, contact pads 106 can comprise an electrically conductive material, such as a metal material, aluminum, copper, an aluminum alloy, or a copper alloy.

In some examples, electronic component 100 can comprise connectors 108 in contact with contact pads 106. Connectors 108 can be electrically connected to electronic component 100 through contact pads 106. In some examples, connectors 108 can comprise or be referred to as bumps, tin-lead (SnPb) bumps, lead-free bumps, CuP, stud bumps, pillars, or posts. In some examples, connectors 108 can be provided on contact pads 106 by plating or a ball-drop process.

In some examples, electronic component 100 can comprise or be referred to as a die, a chip, or a package. In some examples, the overall thickness of electronic component 100 can range from about 50 μm (microns) to about 850 μm. The area of electronic component 100 can range from about 0.5 mm (millimeter)×0.5 mm to about 150 mm×150 mm.

In some examples, pick-and-place equipment can pick up electronic component 100 and place it on the surface of carrier C1. In electronic component 100, second side 104 of the electronic component can be adhered to the upper portion of carrier C1. A temporary bonding layer can be interposed between carrier C1 and electronic component 100. The temporary bonding layer can be a heat-release tape (film) or a light-release tape film, the adhesive strength is weakened or removed by heat or light. In some examples, the temporary bonding layer can be an adhesive layer with an adhesive strength weakened or removed by physical and/or chemical external forces. The temporary bonding layer can be included in carrier C1. Electronic component 100 can be bonded to carrier C1 via the temporary bonding layer. The temporary bonding layer can allow carrier C1 to be separated from electronic component 100 as a subsequent manufacturing step, such as before second substrate 130 is provided.

Carrier C1 can be substantially a planar plate. In some examples, carrier C1 can comprise or be referred to as a plate, a board, glass, a wafer, silicon, a panel, or a strip. In some examples, the thickness of carrier C1 can range from about 300 μm to about 2000 μm. Carrier C1 serves to integrally handle multiple components in the processes of providing electronic component 100, interconnect module 110, package body 119, and first substrate 120.

Interconnect module 110 can be provided on the upper side of carrier C1 and spaced apart from lateral side 103 of electronic component 100. In some examples, electronic component 100 can be positioned at a central region of the upper side of carrier C1, and interconnect module 110 can be positioned at an edge region and spaced apart from lateral side 103 of electronic component 100.

In the present example, interconnect module 110 can comprise stiffener 112, seed layer 114, interconnect 116, and body 118.

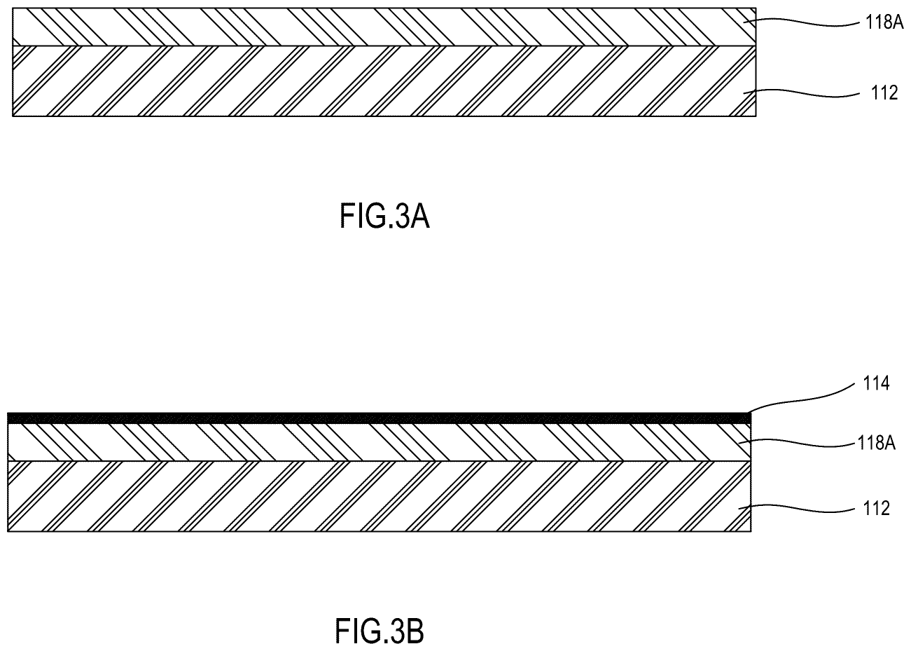

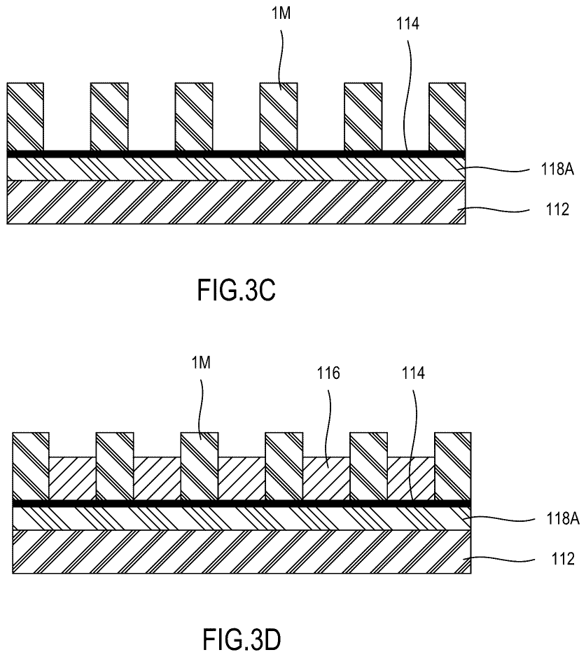

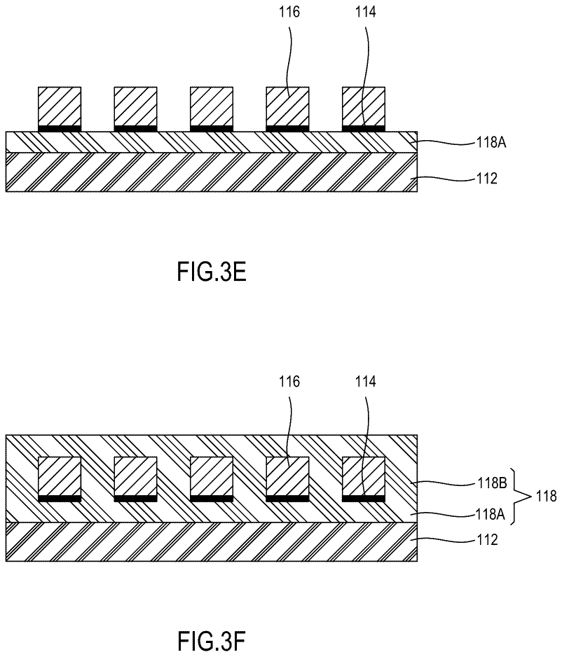

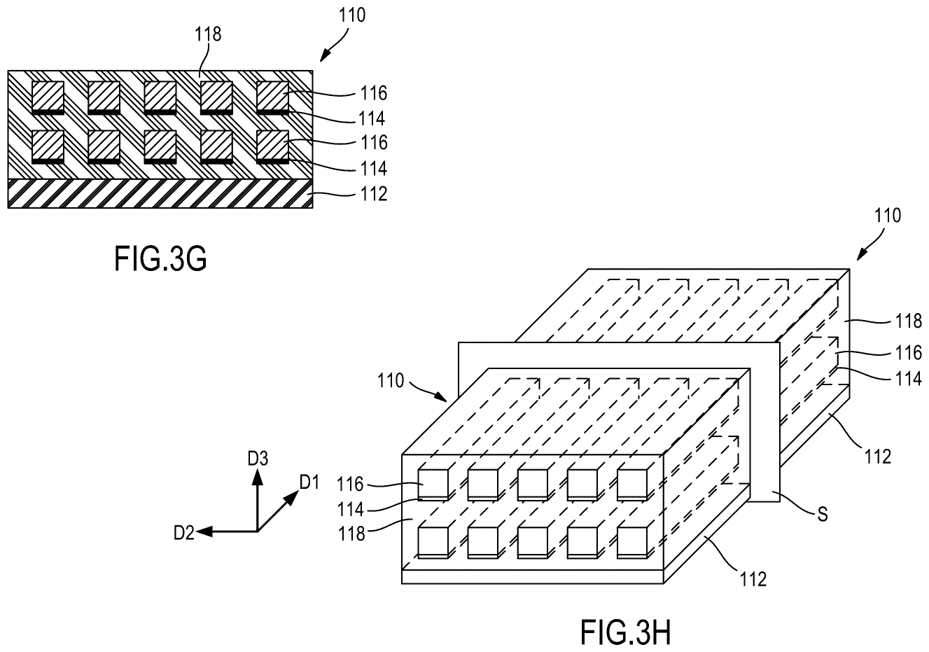

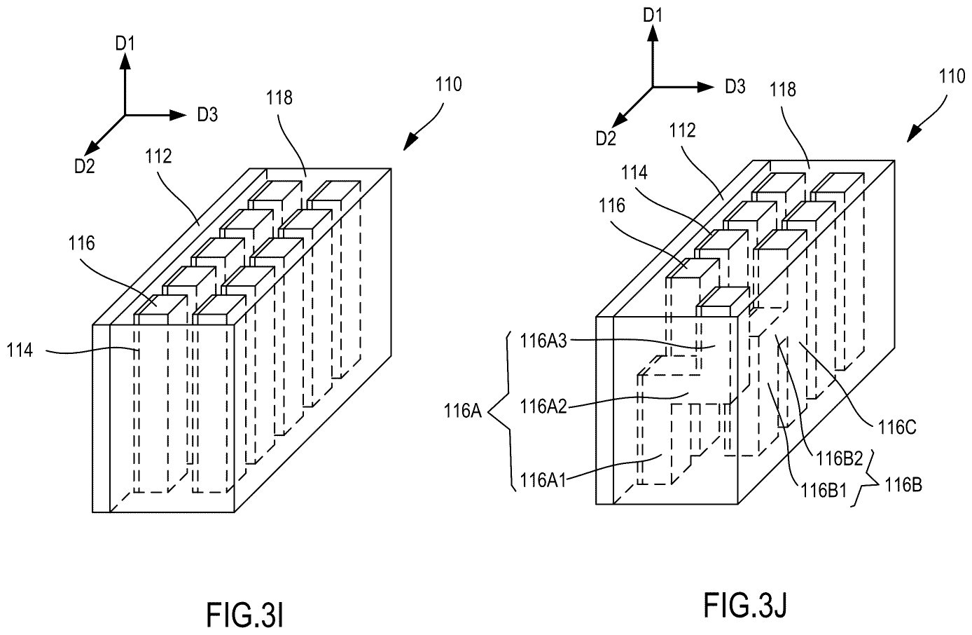

FIGS. 3A to 3G illustrate cross-sectional views of an example method for manufacturing interconnect module 110. FIG. 3A illustrates a cross-sectional view of interconnect module 110 at an early stage of manufacture. In the example illustrated in FIG. 3A, stiffener 112 can be prepared, and body portion 118A can be provided on stiffener 112. In accordance with the present description, the steps described in FIGS. 3A to 3G can be repeated to provide interconnect module 110 with multiple layers (for example, at least two layers) of interconnects 116.

In some examples, stiffener 112 can be a substantially planar plate. Stiffener 112 can comprise or be referred to as a plate, a board, glass, a wafer, a semiconductor (for example, silicon) substrate, a panel, or a strip. In some examples, the thickness of stiffener 112 can range from about 10 μm to about 800 μm. Stiffener 112 serves to integrally handle seed layer 114, interconnect 116, and body portion 118A during the manufacture of interconnect module 110. Stiffener 112 can reinforce and support interconnect module 110.

Body portion 118A can be provided to cover the upper side of stiffener 112. After body portion 118A is provided, an upper region of body portion 118A can be removed using a removal process, such as grinding to provide substantially planar or flat surface. In some examples, body portion 118A can comprise or be referred to as a molding or an encapsulant. For example, body portion 118A can comprise a mold, such as an epoxy mold compound (EMC), a resin, a filler-reinforced polymer, a B-stage pressed film or a gel, and an organic or inorganic dielectric material. Body portion 118A can be provided by compression molding, transfer molding, liquid body molding, vacuum lamination, paste printing, or film-assisted molding. In some examples, the thickness of body portion 118A can range from about 20 μm to about 100 μm. As will be described later, body portion 118A and body portion 118B (FIG. 3F) form body 118 for interconnect module 110. Body portion 118A can be an example of a first body portion.

FIG. 3B illustrates a cross-sectional view of interconnect module 110 at a later stage of manufacture. In the example illustrated in FIG. 3B, seed layer 114 can be provided to cover the upper side of body portion 118A.

In some examples, seed layer 114 can be in contact with the upper side of body portion 118A. In some examples, seed layer 114 can be provided by electroless plating, electrolytic plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, seed layer 114 can be referred to as or comprise a conductive layer, a seed, or a buffer layer. In some examples, seed layer 114 can comprise a copper (Cu), titanium (Ti), titanium tungsten (TiW), titanium nitride (TiN), or tantalum (Ta) barrier layer including copper (Cu) or titanium (Ti). In some examples, the thickness of seed layer 114 can range from about 0.01 μm to about 1 μm.

FIG. 3C illustrates a cross-sectional view of interconnect module 110 at a later stage of manufacture. In the example illustrated in FIG. 3C, mask patterns 1M can be provided to cover the upper side of seed layer 114. Mask patterns 1M can comprise or be referred to as photoresist or a hard mask. After providing mask patterns 1M covering seed layer 114, mask patterns 1M can be patterned through exposure, development, etching, and curing processes. Mask patterns 1M can expose seed layer 114 to extend along a row or column direction. In some examples, the widths of mask patterns 1M can range from about 1 μm to about 250 μm. For example, the widths of mask patterns 1M can be a pitch, a distance between a first one of interconnects 116 to be provided on the upper side of seed layer 114 and an adjacent interconnect 116. In some examples, the height or thickness of mask patterns 1M can range from about 2 μm to about 300 μm.

FIG. 3D illustrates a cross-sectional view of interconnect module 110 at a later stage of manufacture. In the example illustrated in FIG. 3D, interconnects 116 can be provided to cover exposed portions of seed layer 114. In some examples, interconnects 116 can be provided to be in contact with exposed seed layer 114 through mask patterns 1M and to fill a gap between mask patterns 1M. The height or thickness of interconnects 116 can be less than the heights of mask patterns 1M. Interconnects 116 can extend in one direction and be spaced apart from and generally parallel with respect to each other.

In some examples, interconnects 116 can be provided by plating. Interconnects 116 can have rows or columns and can be in contact with and be electrically connected to seed layer 114. In some examples, interconnects 116 can comprise or be referred to as pillars, elongate pillars, plated pillars, elongate plated pillars, posts, through mold vias (TMVs), conductive layers, or conductive patterns. Interconnects 116 can be made of copper, gold, silver, palladium or nickel. In some examples, the heights of interconnects 116 can range from about 1 μm to about 250 μm. In some examples, the widths and pitch of interconnects 116 can range from about 0.01 μm to about 1 μm, respectively.

FIG. 3E illustrates a cross-sectional view of interconnect module 110 at a later stage of manufacture. In the example illustrated in FIG. 3E, mask patterns 1M can be removed. After mask patterns 1M are removed, exposed portions of seed layer 114 that were located under mask patterns 1M can be removed. In some examples, interconnects 116 can act as a mask during the step of removing the exposed portions of seed layer 114. By removing seed layer 114, interconnects 116 can be electrically isolated from each other. By removing mask patterns 1M and seed layer 114, the upper side of body portion 118A can be exposed.

For example, mask patterns 1M can be removed chemically by using acetone, N-methyl-2-pyrrolidone (NMP), tetramethylammonium hydroxide (TMAH), or a mixture of sulfuric acid (H₂SO₄) and hydrogen peroxide (H₂O₂), or can be removed through plasma etching. After mask patterns 1M are removed, exposed seed layer 114 can be removed through wet etching, dry etching, or electrolytic stripping.

FIG. 3F illustrates a cross-sectional view of interconnect module 110 at a later stage of manufacture. In the example illustrated in FIG. 3F, body portion 118B can be provided to cover interconnects 116 and the upper side of body portion 118A exposed through interconnects 116. After body portion 118B is provided, the upper region of body portion 118B can be removed using a removal process, such as grinding to provide a substantially planar or flat surface.

Body portion 118B can be similar to body portion 118A including, for example, similar materials and methods. In other examples, body portion 118B and body portion 118A can have different characteristics including different materials. In some examples, body portion 118A and body portion 118B can form body 118 as a single body. Body 118 can surround interconnects 116 and the upper, lower and side portions of seed layer 114. Body 118 can protect seed layer 114 and interconnects 116 from external elements.

FIG. 3G illustrates a cross-sectional view of interconnect module 110 at a later stage of manufacture. In the example illustrated in FIG. 3G, seed layer 114 and interconnects 116, and body 118 can be sequentially provided on the upper side of the body 118. In some examples, the interconnect module 110 can include at least two layers of interconnects 116. For example, the manufacturing processes of FIGS. 3B to 3F can be repeated on the upper side of body 118 to complete interconnect module 110 having multiple layers. Interconnect module 110 is illustrated as comprising two layers of interconnects 116 but can comprise one layer or three or more layers.

FIG. 3H illustrates a perspective view of completed interconnect module 110 at a later stage of manufacture. As illustrated in FIG. 3H, interconnects 116 can be formed along seed layer 114 in a first direction D1. Interconnect module 110 can be separated into individual interconnect modules 110 by singulating along a singulation line(S) in a second direction D2 that is perpendicular to first direction D1 where interconnects 116 extend lengthwise and are sequentially stacked in a third direction D3. Interconnect module 110 can be provided in a width direction (e.g., first direction D2) perpendicular to the length direction (e.g., second direction D1), rather than in the length direction where the interconnects 116 extend. In this way, interconnects 116 can be implemented without being affected by the height of interconnect module 110.

As illustrated in FIG. 3I individual interconnect modules 110 can be utilized so interconnects 116 are rotated vertically (e.g., first direction D1 oriented upward) to be exposed through the upper and lower sides of body 118. In accordance with the present description, interconnect module 110 can have stiffener 112 positioned at or to cover one side of body 118, and the upper and lower ends of interconnects 116 can be exposed through the upper and lower ends of body 118. Interconnects 116 can comprise seed layer 114 in contact with a side wall adjacent to stiffener 112. In some examples, the upper end of body 118 and the upper ends of interconnects 116 can be coplanar with each other, and the lower end of body 118 and the lower ends of interconnects 116 can be coplanar with each other.

As another example, as illustrated in FIG. 3J, individual interconnect modules 110 can be provided to have various patterns in addition to interconnects 116 that extend only in first direction D1. For example, one interconnect 116A can extend in different directions, such as a first segment 116A1 extending in direction D1, a second segment 116A2 extending in direction D3, and a third segment 116A3 extending in direction D1. In another example, where interconnects 116 are provided in multiple layers, one interconnect 116B can have a first segment 116B1 extending in direction D1 and a second segment 116B2 extending in direction D2 and coupled to another interconnect 116C. More particularly, patterns can be provided to connect interconnects 116 within different layers. Interconnect 116A is an example of a first interconnect coupled to a second interconnect (for example, interconnect 116B) at a location within body 118, which can be an insulative body.

In some examples, the height of interconnect module 110 can be greater than the height of electronic component 100. For example, the height of interconnect module 110 can range from about 50 μm to about 3000 μm. By including stiffener 112, interconnect module 110 can improve strength, interconnects 116 can be provided by plating in the width direction and then rotated vertically to be provided on carrier C1, and thus various heights of interconnects 116 can be implemented and patterns with a fine pitch of interconnects 116 can also be implemented.

FIG. 2B illustrates a cross-sectional view of electronic device 10 at a later stage of manufacture. In the example illustrated in FIG. 2B, package body 119 can be provided to cover the upper side of carrier C1, interconnect modules 110 and electronic component 100.

In some examples, package body 119 can be in contact with the upper side of carrier C1, in contact with electronic component 100, and in contact with surfaces of interconnect module 110. Package body 119 can be in contact with lateral side 111 of interconnect module 110 and lateral side 103 of electronic component 100. Package body 119 can be in contact with contact pads 106 and connectors 108 of electronic component 100. In some examples, package body 119 can be in contact with a lateral side of stiffener 112. In some examples, stiffener 112 faces in direction that is opposite to electronic component 100 towards the lateral outer edge of package body 119. Package body 119 can protect electronic component 100 and interconnect module 110 against physical and environmental hazards.

In some examples, package body 119 can comprise or be referred to as a molding or an encapsulant. For example, package body 119 can comprise an epoxy mold compound, resin, an organic polymer with an inorganic filler, a curing agent, a catalyst, a coupling agent, a colorant, or a flame retardant, and can be provided by compression molding, transfer molding, liquid body molding, vacuum lamination, paste printing, or film-assisted molding.

For example, package body 119 can be provided to cover the upper side of carrier C1, interconnect modules 110, and electronic component 100, and then the upper portion of package body 119 can be removed, and thus upper sides of connectors 108 of electronic component 100 and the upper side of interconnect module 110 can be exposed from package body 119. In some examples, package body 119 remains laterally interposed between connectors 108. In other examples, a dielectric provided as part of electronic component 100 can be interposed between adjacent connectors 108 and contact pads 106. In some examples, the upper side of package body 119 can be coplanar with the upper sides of connectors 108 and the upper side of interconnect module 110. In some examples, the upper sides of interconnects 116 of interconnect module 110 can be coplanar with package body 119. In other examples, electronic component 100 can be exposed from the upper side of package body 119.

In some examples, the upper portion of package body 119 can be removed by a conventional grinding or chemical etching process. When the upper portion of package body 119 is removed, the upper portion of electronic component 100 (e.g., the upper portions of connectors 108) and interconnect modules 110 can also be partially removed. The thickness of package body 119 can be similar to the thicknesses of electronic component 100 and interconnect modules 110. In some examples, the thickness of package body 119 can range from about 20 μm to about 850 μm.

FIG. 2C illustrates a cross-sectional view of electronic device 10 at a later stage of manufacture. In the example illustrated in FIG. 2C, first substrate 120 can be provided to cover package body 119, electronic component 100, and interconnect modules 110.

First substrate 120 can comprise dielectric structure 122 and conductive structure 124. Conductive structure 124 can comprise substrate outer terminals 1241 and substrate inner terminals 1242. In some examples, dielectric structure 122 comprises a plurality of dielectric layers and conductive structure comprises a plurality of conductive layers fabricated in a build-up structure.

Dielectric structure 122 can be provided to cover the upper side of package body 119, the upper sides of connectors 108 of electronic component 100, and the upper side of interconnect module 110. After dielectric structure 122 is provided to cover the upper side of package body 119, electronic component 100, and interconnect module 110, openings can be provided to expose connectors 108 of electronic component 100 and interconnects 116 of interconnect module 110. For example, the openings can be formed by forming a mask pattern on the upper side of dielectric structure 122 and then removing exposed dielectric structure 122 through etching. In some examples, the openings can comprise or be referred to as apertures or holes. In some examples, dielectric structure 122 can comprise or be referred to as a dielectric layer, a coreless layer, or a filler-free layer. For example, dielectric structure 122 can comprise an electrically insulating material such as polyimide (PI), benzocyclobutene (BCB), polybenzoxazole (PBO), resin, or an Ajinomoto buildup film (ABF). In some examples, dielectric structure 122 can be formed by spin coating, spray coating, dip coating, rod coating, or other methods as known to one of ordinary skill in the art. In some examples, the thickness of dielectric structure 122 can range from about 0.01 μm to about 500 μm.

Conductive structure 124 can be provided on the upper side of dielectric structure 122. Conductive structure 124 can be provided to have patterns on the upper side of dielectric structure 122, the upper sides of connectors 108 of electronic component 100, and the upper sides of interconnects 116 of interconnect module 110. Conductive structure 124 can be in contact with and be electrically connected to connectors 108 of electronic component 100 and interconnects 116 of interconnect module 110, respectively. Conductive structure 124 can be a signal distribution element including one or more conductive layers. For example, conductive structure 124 can comprise or be referred to as a trace, a via, a pad, a conductive path, or under-bump-metallurgy (UBM). In some examples, conductive structure 124 can comprise copper, gold, silver, nickel, combinations thereof, alloys thereof, or other materials as known to one of ordinary skill in the art. In some examples, conductive structure 124 can be provided by a plating process such as, for example, an electroplating process or an electroless plating process. The manufacturing process of conductive structure 124 can be similar to the manufacturing process of interconnects 116. In some examples, the thickness of conductive structure 124 can range from about 0.01 μm to about 500 μm.

Dielectric structure 122 can have one or more layers. When dielectric structure 122 is formed of multiple layers, dielectric structure 122 and conductive structure 124 can be alternately laminated. Conductive structure 124 exposed on the upper side of dielectric structure 122 can be referred to as substrate outer terminals 1241. Conductive structure 124 in contact with the upper sides of connectors 108 of electronic component 100 and the upper sides of interconnects 116 of interconnect module 110 can be referred to as substrate inner terminals 1242.

In some examples, completed first substrate 120 can comprise at least one dielectric structure 122 and at least one conductive structure 124. One or more layers or elements of conductive structure 124 can be interleaved with dielectric structure 122. Substrate outer terminals 1241 and substrate inner terminals 1242 can be provided on the outer and inner sides of first substrate 120 so as to be spaced apart from each other in the row or column direction. In some examples, the overall thickness of first substrate 120 can range from about 0.5 μm to about 300 μm.

In some examples, first substrate 120 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in the present disclosure can also comprise an RDL substrate.

In other examples, first substrate 120 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can rereferred to as a printed circuit board (PCB) or a laminate substrate. Such pre-formed substrate can be formed through a semi-additive or modified-semi-additive process. Other substrates in the present disclosure can also comprise a pre-formed substrate.

FIG. 2D illustrates a cross-sectional view of electronic device 10 at a later stage of manufacture. In the example illustrated in FIG. 2D, second substrate 130 can be provided to cover second side 104 of the electronic component, package body 119, and interconnect module 110.

Before second substrate 130 is provided, carrier C2 can be provided to cover the upper side of first substrate 120, and then carrier C1 covering second side 104 of electronic component 100, the lower side of package body 119, and the lower side of interconnect module 110 can be removed. In some examples, heat, light, a chemical solution or a physical force is applied to remove or reduce the adhesion of the temporary bonding layer bonded to second side 104 of electronic component 100, the lower side of package body 119, the lower side of interconnect module 110, and carrier C1. Carrier C1 can then be separated from second side 104 of electronic component 100, the lower side of package body 119, and the lower side of interconnect module 110. The temporary bonding layer of carrier C1 can be separated while remaining attached to carrier C1. Carrier C1 can be removed to expose second side 104 of electronic component 100, the lower side of package body 119, and the lower side of interconnect module 110.

After carrier C1 is removed, electronic component 10 can be flipped so first substrate 120 can be positioned in a downward direction. In some examples, carrier C2 can be positioned on the lower side of first substrate 120 using a temporary adhesive.

Second substrate 130 can comprise dielectric structure 132 and conductive structure 134. Conductive structure 134 can comprise substrate outer terminals 1341 positioned on the upper side of dielectric structure 132 and substrate inner terminals 1342 positioned on the lower side of dielectric structure 132. Substrate inner terminals 1342 can be in contact with and can be coupled to interconnects 116 of interconnect module 110. Second substrate 130 can be electrically connected to electronic component 100 through interconnect module 110 and first substrate 120. Second substrate 130 can have corresponding elements, features, materials or manufacturing methods similar to those of first substrate 120. In some examples, the overall thickness of second substrate 130 can range from about 0.5 μm to about 300 μm.

FIG. 2E illustrates a cross-sectional view of electronic device 10 at a later stage of manufacture. In the example illustrated in FIG. 2E, carrier C2 can be removed from first substrate 120, and external interconnects 150 can be provided to substrate outer terminals 1241 of first substrate 120.

The method for removing carrier C2 can be similar to the method for removing carrier C1. Before removing carrier C2, carrier C3 can be provided on the upper side of second substrate 130, and then flipped so first substrate 120 is positioned in an upward direction and second substrate 130 is positioned on the lower side of electronic device 10.

External interconnects 150 can be in contact with and be electrically connected to substrate outer terminals 1241. External interconnects 150 can be electrically connected to electronic component 100 through conductive structure 124 of first substrate 120. External interconnects 150 can be electrically connected to conductive structure 134 of second substrate 130 through conductive structure 124 of first substrate 120 and interconnect module 110. In some examples, external interconnects 150 can comprise tin (Sn), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, Sn—Ag—Cu, or other materials as known to one of ordinary skill the art. For example, external interconnects 150 can be formed by providing conductive material including solder on substrate outer terminals 1241 through a ball drop process, and then through a reflow process. External interconnects 150 can comprise or be referred to as solder balls, bumps, pads, pillars, copper core solder balls (CCBs), or conductive posts having solder caps formed on copper pillars. In some examples, the sizes of external interconnects 150 can range from about 25 μm to about 500 μm. In some examples, external interconnects 150 can be referred to as external input/output terminals of electronic component 10.

In some examples, electronic component 100′ can be provided on substrate outer terminals 1241 of first substrate 120. Electronic component 100′ can be in contact with and be electrically connected to substrate outer terminals 1241 of first substrate 120. Electronic component 100′ can comprise or be referred to as a die, a chip, a package, or a passive component. In some examples, electronic component 100′ can be electrically connected to electronic component 100 or external interconnects 150 via conductive structure 124 of first substrate 120. In some examples, electronic component 100′ can be electrically connected to conductive structure 134 of second substrate 130 via conductive structure 124 of first substrate 120 and interconnect module 110.

Electronic component 100′ can comprise a first side and a second side. Electronic component 100′ can comprise contact pads and connectors on the first side of the electronic component. The connectors of the electronic component 100′ can be in contact with and be electrically connected to substrate outer terminals 1241 of first substrate 120. Electronic component 100′ can have corresponding elements, features, materials or manufacturing methods similar to those of electronic component 100.

In some examples, underfill 140′ can be provided between electronic component 100′ and first substrate 120. Underfill 140′ can be in contact with the first side of electronic component 100′ and first substrate 120. In some examples, underfill 140′ can be in contact with contact pads and connectors of electronic component 100′.

Underfill 140′ can comprise or be referred to as a dielectric layer or a non-conductive paste and can be free of inorganic fillers. In some examples, underfill 140′ can comprise or be referred to as a capillary underfill (CUF), a nonconductive paste (NCP), a nonconductive film (NCF), an anisotropic conductive film (ACF), or an anisotropic conductive paste (ACP). In some examples, underfill 140′ can be placed between electronic component 100′ and first substrate 120 and can then be cured. Underfill 140′ can prevent electronic component 100′ from being separated from first substrate 120 due to physical and chemical impacts.

In some examples, the thickness of electronic component 100′ can be smaller than the sizes of external interconnects 150. For example, the thickness of electronic component 100′ can range from about 25 μm to about 200 μm.

After electronic component 100′ and external interconnects 150 are provided, a singulation process can be performed to separate electronic device 10 from a panel or plurality of electronic devices 10 into individual electronic devices by singulating first substrate 120, second substrate 130, and package body 119. After the singulation process, carrier C3 of electronic component 10 can be removed from second substrate 130. The removal of carrier C3 can be similar to the removal of carrier C1. In some examples, sawing, laser dicing, etching, combinations thereof, or other methods as known to one of ordinary skill in the art can be used for the singulation process.

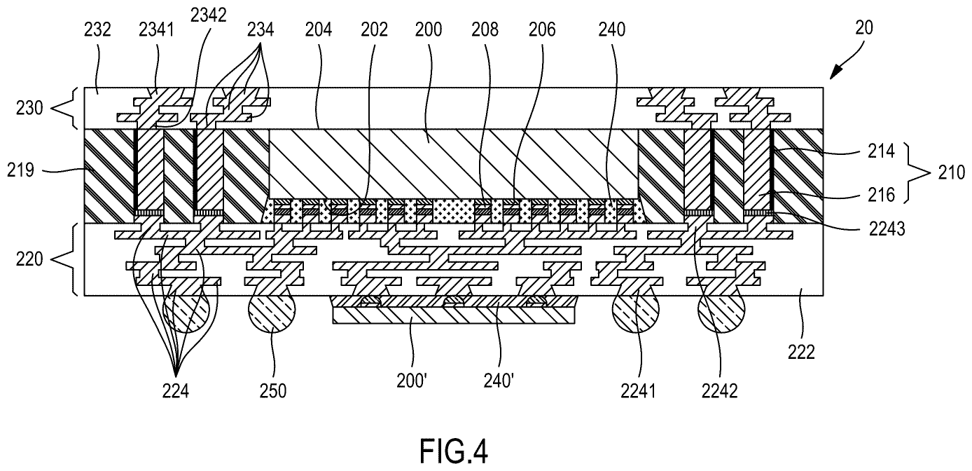

FIG. 4 illustrates a cross-sectional view of an electronic device 20. In the example illustrated in FIG. 4, electronic device 20 can comprise electronic components 200 and 200′, interconnect module 210, package body 219, first substrate 220, second substrate 230, underfills 240 and 240′, and external interconnects 250. Electronic device 20 has some similarity in construction to electronic device 10, such as electronic components 200 and 200′, package body 219, first substrate 220, second substrate 230, underfill 240′, and external interconnects 250. In addition, interconnect module 210 can comprise seed layer 214 and interconnects 216. Electronic device 20 has certain differences including other features of interconnect module 210, substrate inner terminals 2242, solder 2243, and underfill 240.

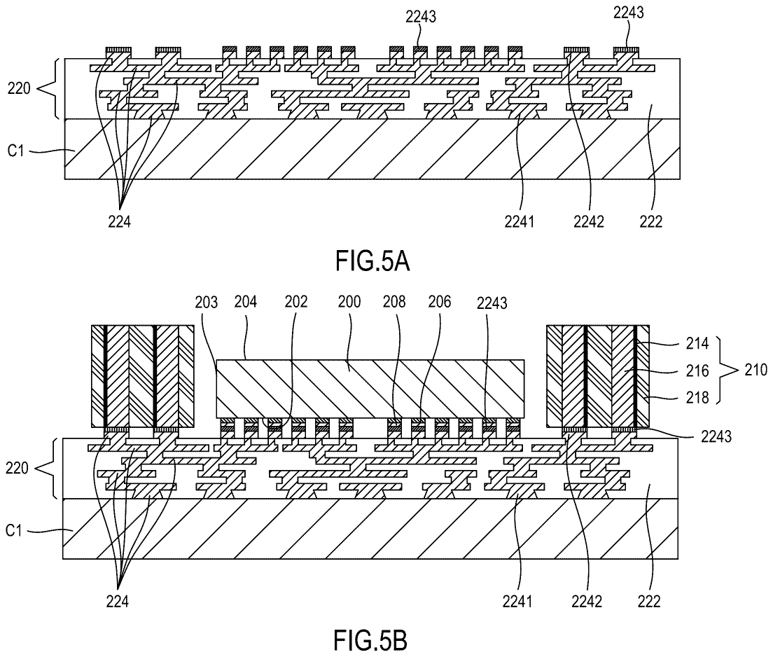

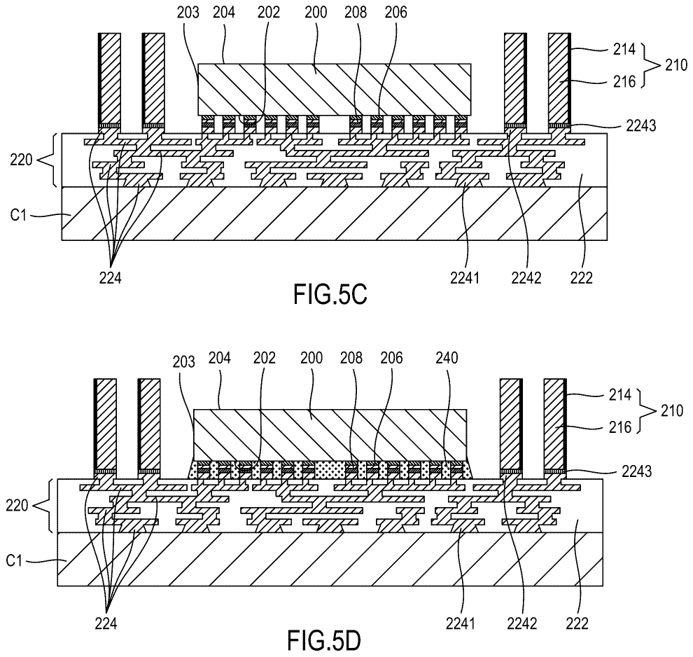

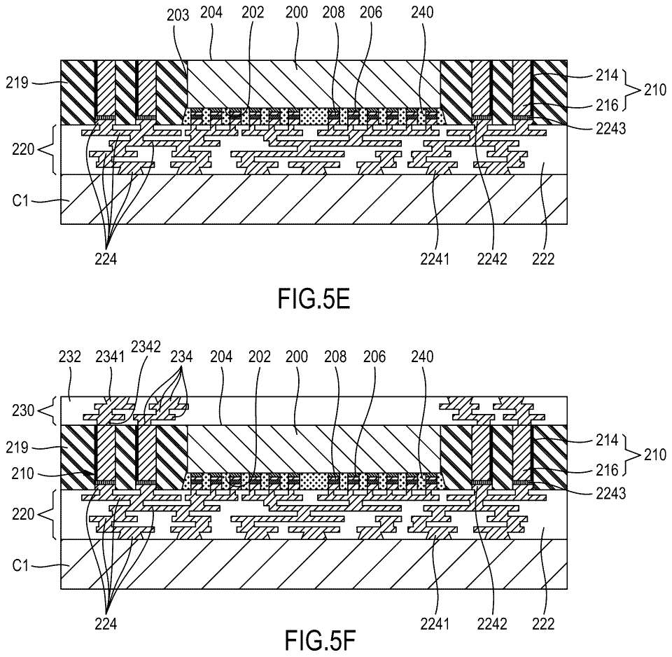

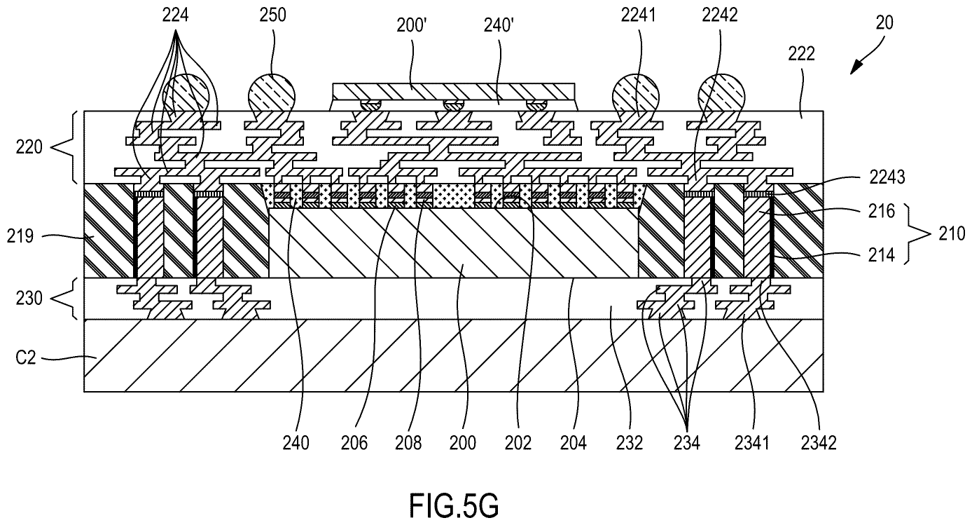

FIGS. 5A to 5G illustrate cross-sectional views of an example method for manufacturing example electronic device 20.

FIG. 5A illustrates a cross-sectional view of electronic device 20 at an early stage of manufacture. In the example illustrated in FIG. 5A, first substrate 220 can be provided on the surface of carrier C1. Carrier C1 can have corresponding elements, features, materials or manufacturing methods similar to those of carrier C1 described with the example method of manufacturing electronic device 10. First substrate 220 can comprise dielectric structure 222 and conductive structure 224. Conductive structure 224 can comprise substrate outer terminals 2241 and substrate inner terminals 2242. In the present examples, substrate inner terminals 2242 can extend or protrude outward from dielectric structure 222. First substrate 220 can have corresponding elements, features, materials or manufacturing methods similar to those of first substrate 120 of electronic device 10. In some examples, first substrate 220 can comprise solder 2243 provided on the surfaces of substrate inner terminals 2242. Solder 2243 can facilitate contact and electrical connection with electronic component 200 and interconnect module 210. In some examples, the solder 2243 can comprise or be referred to as a conductive member or a bonding member.

FIG. 5B illustrates a cross-sectional view of electronic device 20 at a later stage of manufacture. In the example illustrated in FIG. 5B, electronic component 200 and interconnect module 210 can be provided on the upper side of first substrate 220.

Electronic component 200 can comprise first side 202 and second side 204. Second side 204 of electronic component 200 can be opposite to first side 202 of electronic component 200. In some examples, first side 202 of the electronic component 200 can comprise or be referred to as an active side, and second side 204 of electronic component 20 can comprise or be referred to as an inactive side. Electronic component 200 can comprise a lateral side 203 connecting first side 202 and second side 204. Electronic component 200 can comprise contact pads 206 on first side 202 and connectors 208 in contact with contact pads 206. Electronic component 200 can have corresponding elements, features, materials or manufacturing methods similar to those of electronic component 100 of electronic device 10.

In electronic component 200, connectors 208 can be electrically connected to substrate inner terminals 2242 of first substrate 220 through solder 2243. In some examples, pick-and-place equipment can pick up electronic component 200 and place it on first substrate 220. Connectors 208 of electronic component 200 can be positioned on solder 2243 covering substrate inner terminals 2242 of first substrate 220. Subsequently, contact pads 206 of electronic component 200 can be in contact with and be bonded to substrate inner terminals 2242 through connectors 208 and solder 2243 through a reflow or thermal compression bonding process.

Interconnect module 210 can be provided on the upper side of first substrate 220 laterally spaced apart from lateral side 203 of electronic component 200. Electronic component 200 can be positioned in the upper center region of first substrate 220, and interconnect module 210 can be positioned in the edge region laterally spaced apart from lateral side 203 of electronic component 200. In the present example, interconnect module 210 can comprise seed layer 214, interconnects 216, and body 218.

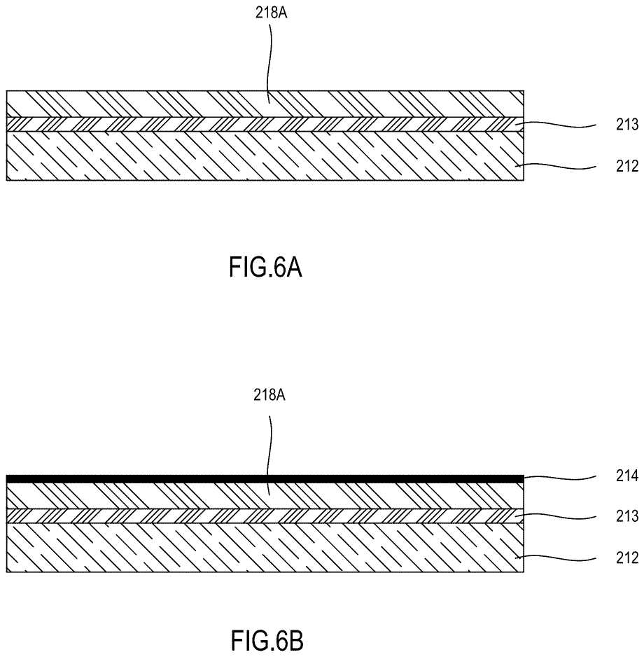

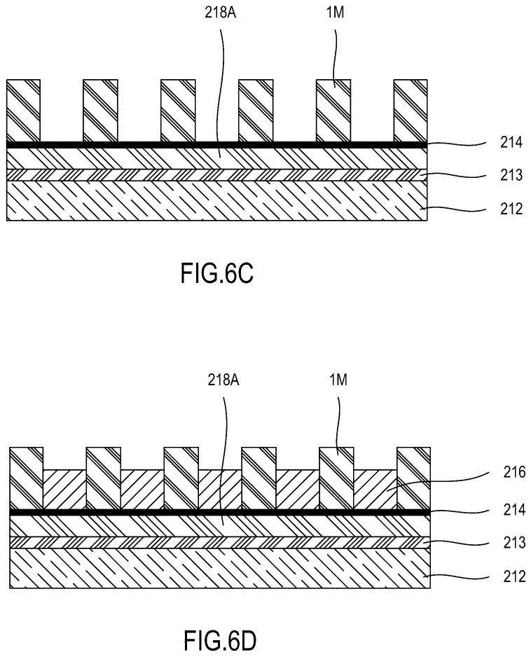

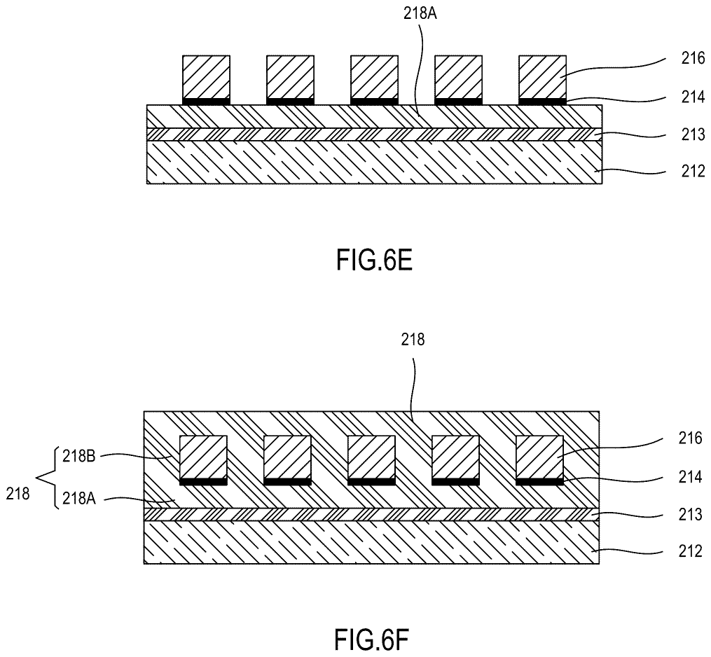

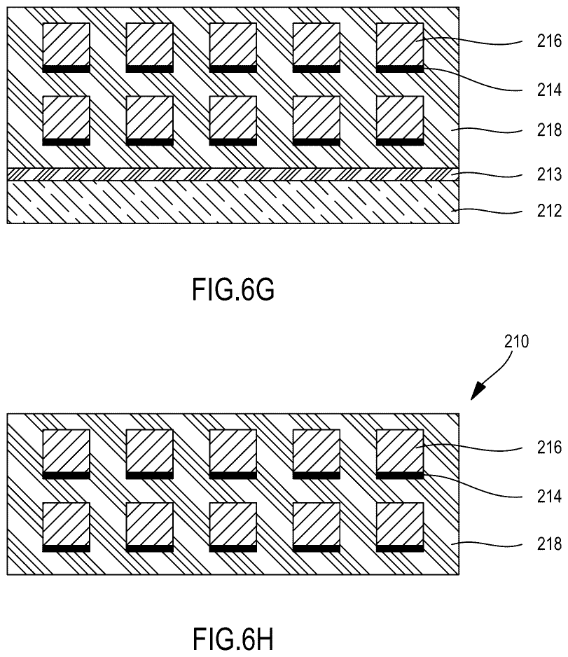

FIGS. 6A to 6H illustrate cross-sectional views of an example method for manufacturing interconnect module 210. FIG. 6A illustrates a cross-sectional view of interconnect module 210 at an early stage of manufacture. In the example illustrated in FIG. 6A, carrier 212 can be prepared, and body portion 218A can be provided on the upper side of carrier 212. Carrier 212 can be a flat plate and can comprise temporary bonding layer 213 on the upper side of carrier 212 so that temporary bonding layer 213 can be located between carrier 212 and body 218. Carrier 212 can be an example of a second carrier. In accordance with the present description, the steps described in FIGS. 6A to 6H can be repeated to provide interconnect module 210 with multiple layers (for example, at least two layers) of interconnects 216.

Carrier 212 and temporary bonding layer 213 can have corresponding elements, features, materials or manufacturing methods similar to those of carrier C1 used in the manufacture of electronic device 10 and the temporary bonding layer provided on the upper side of carrier C1. Body portion 218A can be provided to cover the upper side of temporary bonding layer 213. After body portion 218A is provided, in some examples an upper part of body portion 218A can be removed using a planarization process to provide body portion 218A with flatter or more planar upper side. In some examples, body portion 218A can comprise or be referred to as a molding or an encapsulant. In other examples, body portion 218A can comprise a photoresist. In some examples, body portion 218A can be provided through coating. In some examples, the thickness of body portion 218A can range from about 20 μm to about 100 μm. As will be described later, body portion 218A and body portion 218B (FIG. 6F) form body 218 for interconnect module 210.

FIG. 6B illustrates a cross-sectional view of interconnect module 210 at a later stage of manufacture. In the example illustrated in FIG. 6B, seed layer 214 can be provided to cover the upper side of body 218.

In some examples, seed layer 214 can be in contact with the upper side of body portion 218A. Seed layer 214 can have corresponding elements, features, materials or manufacturing methods similar to those of seed layer 114 interconnect module 110.

FIG. 6C illustrates a cross-sectional view of interconnect module 210 at a later stage of manufacture. In the example illustrated in FIG. 6C, mask patterns 1M can be provided to cover the upper side of seed layer 214. Mask patterns 1M can comprise or be referred to as photoresist. Mask patterns 1M can have corresponding elements, features, materials or manufacturing methods similar to those of mask patterns 1M described in the manufacture of interconnect module 110.

FIG. 6D illustrates a cross-sectional view of interconnect module 210 at a later stage of manufacture. In the example illustrated in FIG. 6D, interconnects 216 can be provided to cover exposed seed layer 214. Interconnects 216 can be provided to be in contact with exposed seed layer 214 through mask patterns 1M and to fill gaps in mask patterns 1M. Interconnects 216 can have corresponding elements, features, materials or manufacturing methods similar to those of interconnects 116 of interconnect module 110.

FIG. 6E illustrates a cross-sectional view of interconnect module 210 at a later stage of manufacture. In the example illustrated in FIG. 6E, mask patterns 1M can be removed. After mask patterns 1M are removed, seed layer 214 located on the lower sides of mask patterns 1M can also be removed. By removing seed layer 214, respective interconnects 216 can be electrically isolated. The method for removing mask patterns 1M and seed layer 214 can be similar to the method for removing mask patterns 1M and seed layer 114 of interconnect module 110. Although in some examples, mask patterns 1M and body portion 218A can both comprise photoresist, body portion 218A can be covered by seed layer 214, and thus body portion 218A can remain when mask patterns 1M are removed.

FIG. 6F illustrates a cross-sectional view of interconnect module 210 at a later stage of manufacture. In the example illustrated in FIG. 6F, body portion 218B can be provided to cover interconnects 216 and the upper side of body portion 218A exposed through interconnects 216. In some examples, the upper portion of body portion 218B can then be removed using a removal process, such as grinding to provide a substantially planar or flat surface.

Body portion 218B can be similar material to body portion 218A including similar materials and methods. In other examples, body portion 218B and body portion 218A can have different characteristics including different materials. In some examples, body portion 218A and body portion 218B can form body 218 as a single body. Body 218 can surround interconnects 216 and the upper, lower and side portions of seed layer 214. Body 218 can protect seed layer 214 and interconnects 216 from external elements.

FIG. 6G illustrates a cross-sectional view of interconnect module 210 at a later stage of manufacture. In the example illustrated in FIG. 6G, seed layer 214 and interconnects 216, and body 218 can be sequentially provided on the upper side of body 218. Interconnect module 210 can comprise two layers of interconnects 216. For example, the manufacturing stages illustrated in FIGS. 6B to 6F can be repeated on the upper side of body 218 to complete interconnect module 210 having multiple layers. Interconnect module 210 is illustrated as comprising two layers of interconnects 216 but can comprise one layer or three or more layers.

FIG. 6H illustrates a cross-sectional view of interconnect module 210 at a later stage of manufacture. In the example illustrated in FIG. 6H, carrier 212 can be removed from the lower side of body 218. The method for removing carrier 212 can be similar to the method for removing carrier C1 in the manufacture of electronic device 10. Temporary bonding layer 213 can be removed together with carrier 212. Interconnect module 210 where carrier 212 has been removed can be separated into individual interconnect modules 210 by singulation, like the interconnect module 110 illustrated in FIG. 3H.

Interconnect module 210 can be oriented so that interconnects 216 are exposed through the upper and lower sides of body 218 and thus, can be provided on first substrate 220. Interconnect module 210 can comprise seed layer 214 in contact with one side wall of each of interconnects 216 and the upper and lower sides of interconnects 216 are exposed through body 218. In accordance with the present description, the upper and lower ends of interconnects 216 can be exposed through the upper and lower ends of body 218. Interconnects 216 can comprise seed layer 214 in contact with one side wall only similar interconnect 216 In some examples, the upper end of body 218 and the upper ends of interconnects 216 can be coplanar with each other, and the lower end of body 218 and the lower ends of interconnects 116 can be coplanar with each other.

In some examples, the height of interconnect module 210 can be greater than the height of electronic component 200. For example, the height of interconnect module 210 can range from about 50 μm to about 3000 μm. Interconnects 216 can be provided by plating in the width direction and then rotated vertically to be provided on first substrate 220, and thus various heights of interconnects 216 can be implemented and patterns with a fine pitch of interconnects 216 can also be implemented.

FIG. 5C illustrates a cross-sectional view of electronic device 20 at a later stage of manufacture. In the example illustrated in FIG. 5C, body 218 can be removed from interconnect module 210 leaving interconnects 216 and seed layer 114 in place on substrate 220.

Body 218 can be removed chemically by using acetone, N-methyl-2-pyrrolidone (NMP), tetramethylammonium hydroxide (TMAH), or a mixture of sulfuric acid (H₂SO₄) and hydrogen peroxide (H₂O₂), or can be removed through plasma etching. After body 218 is removed, seed layer 214 and the side walls of interconnects 216 can be exposed. In this way, interconnect module 210 where body 218 has been removed can comprise individually separated interconnects 216. Interconnect module 210 can comprise respective interconnects 216 and seed layer 214 covering one side wall of each of interconnects 216. In the present example, the opposing side wall of each of interconnects 216 is devoid of seed layer 214.

FIG. 5D illustrates a cross-sectional view of electronic device 20 at a later stage of manufacture. In the example illustrated in FIG. 5D, underfill 240 can be provided between electronic component 200 and first substrate 220. Underfill 240 can be in contact with first side 202 of electronic component 200 and the upper side of first substrate 220. In some examples, underfill 240 can be in contact with contact pads 206 and connectors 208 of electronic component 200. Underfill 240 can comprise or be referred to as a dielectric layer or a non-conductive paste and can be free of inorganic fillers. In some examples, underfill 240 can comprise or be referred to as a capillary underfill (CUF), a nonconductive paste (NCP), a nonconductive film (NCF), an anisotropic conductive film (ACF), or an anisotropic conductive paste (ACP). In some examples, when electronic device 20 comprises a molded underfill (MUF), underfill 240 can be considered part of package body 119. In some examples, underfill 240 can be positioned between electronic component 200 and first substrate 220 and can then be cured. Underfill 240 can prevent electronic component 200 from being separated from first substrate 220 due to physical or chemical impacts.

FIG. 5E illustrates a cross-sectional view of electronic device 20 at a later stage of manufacture. In the example illustrated in FIG. 5E, package body 219 can be provided to cover first substrate 220, interconnect module 210, electronic component 200, and underfill 240. In the present example, package body 219 is interposed between lateral side 203 of electronic component 200 and interconnect module 210. Package body 219 can have corresponding elements, features, materials or manufacturing methods similar to those of package body 119 of electronic device 10. In some examples, the upper side of package body 219 can be coplanar with the upper side of interconnect module 210 and second side 204 of electronic component 200.

FIG. 5F illustrates a cross-sectional view of electronic device 20 at a later stage of manufacture. In the example illustrated in FIG. 5F, second substrate 230 can be provided to cover the upper side of package body 219, the upper side of interconnect module 210, and second side 204 of electronic component 200. Second substrate 230 can comprise dielectric structure 232 and conductive structure 234. Conductive structure 234 can comprise substrate outer terminals 2341 positioned on the upper side and substrate inner terminals 2342 positioned on the lower side. Substrate inner terminals 2342 can be in contact with and be electrically connected to interconnects 216 of interconnect module 210. Second substrate 230 can be electrically connected to electronic component 100 through interconnect module 210 and first substrate 220. Second substrate 230 can have corresponding elements, features, materials or manufacturing methods similar to those of second substrate 130 of electronic device 10.

FIG. 5G illustrates a cross-sectional view of electronic device 20 at a later stage of manufacture. In the example illustrated in FIG. 5G, carrier C1 can be removed from first substrate 220, and external interconnects 250 can be provided to substrate outer terminals 2241 of first substrate 220.

The method for removing carrier C1 can be similar to the method for removing carrier C1 in the manufacture of electronic component 10. Before removing carrier C1, carrier C2 can be provided on the upper side of second substrate 230, and then flipped so first substrate 220 is positioned in an upward direction and second substrate 230 is positioned on the lower side with respect to electronic component 200.

External interconnects 250 can be in contact with and be electrically connected to substrate outer terminals 2241. External interconnects 250 can have corresponding elements, features, materials or manufacturing methods similar to those of external interconnects 150 of electronic device 10.

In some examples, electronic component 200′ can be provided on substrate outer terminals 2241 of first substrate 220. Electronic component 200′ can have corresponding elements, features, materials or manufacturing methods similar to those of electronic component 100′ of electronic device 10. In some examples, underfill 240′ can be provided between electronic component 200′ and first substrate 220. Underfill 240′ can have corresponding elements, features, materials or manufacturing methods similar to those of underfill 240.

After providing electronic component 200′ and external interconnects 250, a singulation process can be performed to separate electronic device 20 from a panel or plurality of electronic devices 20 into individual electronic devices by singulating first substrate 220, second substrate 230, and package body 219. by singulating first substrate 220, second substrate 230, and package body 219. After the singulation process of electronic device 20, carrier C2 can be removed from second substrate 230. The removal of carrier C2 can be similar to the removal of carrier C1 in the manufacture of electronic device 10.

From all the foregoing, one of ordinary skill in the art can determine that according to an example, a method of providing an interconnect module comprises a) providing a stiffener comprising a stiffener upper side; b) providing a first body portion over the stiffener upper side; c) providing the a seed layer over the first body portion; d) providing mask patterns over the seed layer, wherein portions of the seed layer are exposed from the patterns along a first direction (for example, direction D1 in FIG. 3H); e) plating the interconnects along the exposed portions of the seed layer in the first direction; f) removing the mask patterns; g) removing other portions of the seed layer exposed after removing mask patterns; h) providing a second body portion over the interconnects; i) singulating through the second portion, the interconnects, the first body portions and stiffener along a second direction (for example, direction D2 in FIG. 3H) different than the first direction, wherein the stiffener remains as part of the interconnect module. In another example, the method includes the step of placing the interconnect module adjacent to an upper side of a carrier. In a further example, the method includes repeating steps a) through h) before the step of singulating to provide the interconnect module comprises at least two layers of interconnects. See for example, FIGS. 2A through 3H.

From all the foregoing, one of ordinary skill in the art can determine that according to an example, a method of providing an interconnect module can comprise a) providing a second carrier comprising an upper side; b) providing a temporary bonding layer on the upper side of the second carrier; c) providing a first body portion over the temporary bonding layer; d) providing a seed layer over the first body portion; e) providing mask patterns over the seed layer, wherein portions of the seed layer are exposed from the mask patterns in a first direction; f) plating the interconnects along the exposed portion of the seed layer in the first direction; g) removing the mask patterns; h) removing other portions of the seed layer exposed after removing the mask patterns; i) providing a second body portion over the interconnects; j) removing the second carrier; k) singulating through the second body portion, the interconnects, and the first body portion along a second direction different than the first direction. In another example, the method includes l) coupling ends of the interconnects to the first substrate inner terminals. In further example, the method includes m) after coupling the first ends of the interconnects, removing the first body portion and the second body portion before providing the package body. In another example, providing the package body includes providing the package body interposed between the interconnects after removing the first body portion and the second body portion. In a further example, the method includes repeating steps a) through i) before the step of removing the second carrier to provide the interconnect module comprising at least two layers of interconnects. See for example, FIGS. 5A through 6H.

In summary, structures and methods have been described that provide pillar interconnect modules with finer pitch and increased height compared to previous approaches. In some examples, the conductor heights for the interconnect module are provided by forming (for example, by plating) the structures lengthwise in the x or y directions as opposed to the z direction. In some examples, the height and aspect ratio of the interconnect module can be selected using a singulation process. In some examples, the interconnect modules can comprise vertical redistribution configurations. In some examples, the interconnect modules include a stiffener along one side of the interconnect module. Among other things, the structures and methods provide for improved integration and smaller package size.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a first substrate, comprising:
a first substrate top side;
a first substrate lower side opposite to the first substrate top side;
a first dielectric structure; and
a first conductive structure, comprising:
first substrate inner terminals adjacent to the first substrate top side; and
first substrate outer terminals adjacent to the first substrate lower side and coupled to the first substrate inner terminals;
a first electronic component, comprising:
a first side coupled to the first substrate inner terminals;
a second side opposite to the first side; and
a lateral side connecting the first side to the second side;
an interconnect module, comprising:
interconnects laterally spaced apart, wherein each of the interconnects comprises a first lateral side, a second lateral side opposite to the first lateral side, a first end, and a second end opposite to the first end; and
a seed layer on the first lateral side but not the second lateral side of each of the interconnects; and
a package body covering the first substrate top side, portions of the interconnect module and the lateral side of the first electronic component;
wherein:
the first end of each of the interconnects is coupled to the first substrate inner terminals.

2. The electronic device of claim 1, wherein the interconnect module comprises:
an insulative body interposed between the interconnects.

3. The electronic device of claim 2, wherein:
the interconnect module comprises a stiffener; and
the stiffener defines an outer lateral side of the interconnect module.

4. The electronic device of claim 3, wherein:
the stiffener comprises a semiconductor substrate.

5. The electronic device of claim 1, wherein:
the package body is interposed between the interconnects; and
the first end and the second end of each of the interconnects are exposed from the package body.

6. The electronic device of claim 1, wherein:
the interconnect module comprises an insulative body interposed between adjacent interconnects;
the interconnects comprise a first interconnect and a second interconnect; and
the first interconnect is coupled to the second interconnect at a location within the insulative body.

7. The electronic device of claim 1, further comprising:
a second substrate comprising:
a second dielectric structure; and
a second conductive structure coupled to the interconnect module.

8. The electronic device of claim 7, further comprising:
a second electronic component;
wherein:
the second substrate comprises a redistribution layer (RDL) substrate;
the second substrate comprises a second substrate inner side and a second substrate outer side;
the second substrate inner side adjoins the interconnect module and the package body; and
the second electronic component is coupled to the first substrate lower side.

9. The electronic device of claim 1, further comprising:
external interconnects coupled to the first substrate outer terminals;
wherein:
the first substrate comprises a redistribution layer (RDL) substrate.

10. The electronic device of claim 1, wherein:
the first substrate inner terminals protrude outward from the first dielectric structure.

11. The electronic device of claim 10, further comprising:
a bonding member interposed between the interconnects and the first substrate inner terminals.

12. An electronic device, comprising:
a first substrate, comprising:
a first substrate top side;
a first substrate lower side opposite to the first substrate top side;
a first dielectric structure; and
a first conductive structure, comprising:
first substrate inner terminals adjacent to the first substrate top side; and
first substrate outer terminals adjacent to the first substrate lower side and coupled to the first substrate inner terminals;
a second substrate, comprising:
a second substrate top side;
a second substrate lower side opposite to the second substrate top side;
a second dielectric structure; and
a second conductive structure comprising:
second substrate inner terminals adjacent to the second substrate lower side; and
second substrate outer terminals adjacent to the second substrate top side and coupled to the second substrate inner terminals;
a first electronic component, comprising:
a first side coupled to the first substrate inner terminals;
a second side opposite to the first side; and
a lateral side connecting the first side to the second side;
an interconnect module, comprising:
interconnects laterally spaced apart, wherein each of the interconnects comprises a first lateral side, a second lateral side opposite to the first lateral side, a first end, and a second end opposite to the first end; and
a seed layer on the first lateral side of each of the interconnects; and
a package body covering the first substrate top side, the second substrate lower side, portions of the interconnect module and the lateral side of the first electronic component;
wherein:
the interconnect module comprises at least two layers of the interconnects;
the first end of each of the interconnects is coupled to the first substrate inner terminals; and
the second end of each of the interconnects is coupled to the second substrate inner terminals.

13. The electronic device of claim 12, wherein the interconnect module comprises:
an insulative body interposed between the interconnects; and
a stiffener;
wherein:
the interconnect module comprises an outer lateral side; and
the stiffener defines the outer lateral side.

14. The electronic device of claim 12, wherein:
the package body is interposed between the interconnects.

15. A method of manufacturing an electronic device, comprising:
providing a first electronic component, comprising:
a first side;
a second side opposite to the first side;
a lateral side connecting the first side to the second side; and
connectors adjacent to the first side;
providing an interconnect module, comprising:
interconnects laterally spaced apart, wherein each of the interconnects comprises a first lateral side, a second lateral side opposite to the first lateral side, a first end, and a second end opposite to the first end; and
a seed layer on the first lateral side but not the second lateral side of each of the interconnects;
providing a package body covering portions of the interconnect module and the first electronic component; and
providing a first substrate comprising:
a first dielectric structure; and
a first conductive structure comprising:
first substrate inner terminals; and
first substrate outer terminals exposed from the first dielectric structure and coupled to the first substrate inner terminals;
wherein:
the first end of each of the interconnects and the connectors are coupled to the first substrate inner terminals.

16. The method of claim 15, further comprising:
providing a first carrier comprising an upper side; and
providing the first electronic component comprises placing the second side of the first electronic component adjacent to the upper side of the first carrier;
wherein:
providing the interconnect module comprises:
a. providing a stiffener comprising a stiffener upper side;
b. providing a first body portion over the stiffener upper side;
c. providing the seed layer over the first body portion;
d. providing mask patterns over the seed layer, wherein portions of the seed layer are exposed from the mask patterns along a first direction;
e. plating the interconnects along the exposed portions of the seed layer in the first direction;
f. removing the mask patterns;
g. removing other portions of the seed layer exposed after removing the mask patterns;
h. providing a second body portion over the interconnects;
i. singulating through the second body portion, the interconnects, the first body portion and the stiffener along a second direction different than the first direction, wherein the stiffener remains as part of the interconnect module; and
j. placing the interconnect module adjacent to the upper side of the first carrier; and
providing the first substrate comprises providing the first substrate after providing the package body.

17. The method of claim 16, further comprising:
repeating steps a through h before the step of singulating to provide the interconnect module comprising at least two layers of the interconnects.

18. The method of claim 15, further comprising:
providing a first carrier comprising an upper side;
wherein:
providing the first substrate comprising providing the first substrate over the upper side of the first carrier;
providing the first electronic component comprises coupling the connectors to the first substrate inner terminals;
providing the interconnect module comprises:
a. providing a second carrier comprising an upper side;
b. providing a temporary bonding layer on the upper side of the second carrier;
c. providing a first body portion over the temporary bonding layer;
d. providing the seed layer over the first body portion;
e. providing mask patterns over the seed layer, wherein portions of the seed layer are exposed from the mask patterns along a first direction;
f. plating the interconnects along the exposed portions of the seed layer in the first direction;
g. removing the mask patterns;
h. removing other portions of the seed layer exposed after removing the mask patterns;
i. providing a second body portion over the interconnects;
j. removing the second carrier;
k. singulating through the second body portion, the interconnects, and the first body portion along a second direction different than the first direction;
l. coupling the first end of each of the interconnects to the first substrate inner terminals; and
m. after coupling the first end of each of the interconnects, removing the first body portion and the second body portion before providing the package body; and
providing the package body comprises providing the package body interposed between the interconnects.

19. The method of claim 18, further comprising:
repeating steps a through i before the step of removing the second carrier to provide the interconnect module comprising at least two layers of the interconnects.

20. The method of claim 15, further comprising:
providing a second substrate coupled to the second end of each of the interconnects.
